(19) United States
(12) Patent Application Publication
(10) Pub. No.: US 2017/0086326 A1
(43) Pub. Date: Mar. 23, 2017

(54) ELECTRONIC DEVICE ENCLOSURE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YONG PENG, Wuhan (CN); HE-TAO HAN, wuhan (CN); JUN-HUA TAN, wuhan (CN); XIAO-ZHONG JING, Wuhan (CN); YI-SHENG LIN, New Taipei (TW); CHUNG CHAI, New Taipei (TW); LIANG-CHIN WANG, New Taipei (TW)

(21) Appl. No.: 14/880,697

(22) Filed: Oct. 12, 2015

(30) Foreign Application Priority Data
Sep. 18, 2015 (CN) 201510596665.8

(51) Int. Cl. H05K 7/16; H05K 7/14; H05K 5/02

(52) U.S. Cl. CPC H05K 7/16; H05K 5/0217; H05K 7/1432

(57) ABSTRACT

An electronic device enclosure includes a chassis, a bracket, a shaft and a supporting member. The bracket is rotatably connected to the chassis through the shaft. The supporting member is sheathed with the shaft. Two opposite ends of the supporting member are respectively fixed to the chassis and the bracket. When the bracket rotates in a first direction relative to the chassis, the supporting member is elastically deformable to support the bracket preventing the bracket from rotating towards a second direction relative to the chassis. And the first direction is opposite to the second direction.

### CROSS-REFERENCE TO RELATED APPLICATIONS

This application claims priority to Chinese Patent Application No. 201510596665.8 filed on Sep. 18, 2015, the contents of which are incorporated by reference herein.

### FIELD

The subject matter herein generally relates to an electronic device enclosure for positioning a power supply.

### BACKGROUND

A power supply device is required to provide power to many electronic devices, for example, desktop computers, servers, and Internet appliances. In most cases, the power supply needs to be moved while a component of the electronic devices is being repaired.

### BRIEF DESCRIPTION OF THE DRAWINGS

Implementations of the present technology will now be described, by way of example only, with reference to the attached figures.

FIG. 1 is an exploded, isometric view of one embodiment of an electronic device enclosure.

FIG. 2 is an isometric view of a positioning member of the electronic device enclosure of FIG. 1.

FIG. 3 is an isometric view of a supporting member and a mounting member of the electronic device enclosure of FIG. 1.

FIG. 4 is similar to FIG. 1, but viewed from another angle.

FIG. 5 is an assembled, isometric view of the electronic device enclosure of FIG. 1.

FIG. 6 is an enlarged view of a circled portion VI of FIG. 5.

FIG. 7 is an assembled, isometric view of the electronic device enclosure of FIG. 5, in a working state.

FIG. 8 is an enlarged view of a circled portion VIII of FIG. 7.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to an electronic device enclosure. The electronic device enclosure includes a chassis, a bracket, a shaft and a supporting member. The bracket is rotatably connected to the chassis via the shaft. The supporting member is sheathed around the shaft. Two opposite ends of the supporting member are respectively fixed to the chassis and the bracket. When the bracket rotates in a first direction relative to the chassis, the supporting member is elastically deformable to support the bracket preventing the bracket from rotating towards a second direction relative to the chassis. And the first direction is opposite to the second direction.

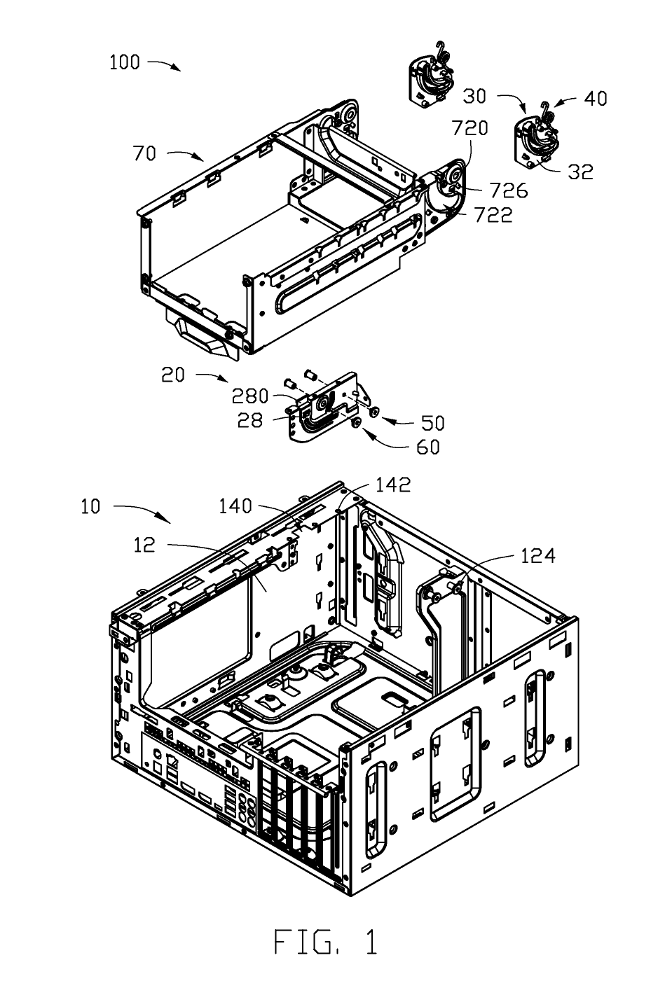

FIG. 1 illustrates one embodiment of an electronic device enclosure 100. The electronic device enclosure 100 includes a chassis 10, a positioning member 20, two mounting members 30, two supporting members 40, a shaft 50, a rotary member 60, and a bracket 70.

The chassis 10 includes two side plates 12 and a first edge 14. The two side plates 12 can be substantially parallel to each other. The first edge 14 extends substantially perpendicular from one of the two side plates 12. Each side plate 12 defines a mounting hole 120. A receiving space 140 and a plurality of first locking holes 142 are defined in the first edge 14. A first gap 124 is defined in one of the two side plates 12 away from the first edge 14.

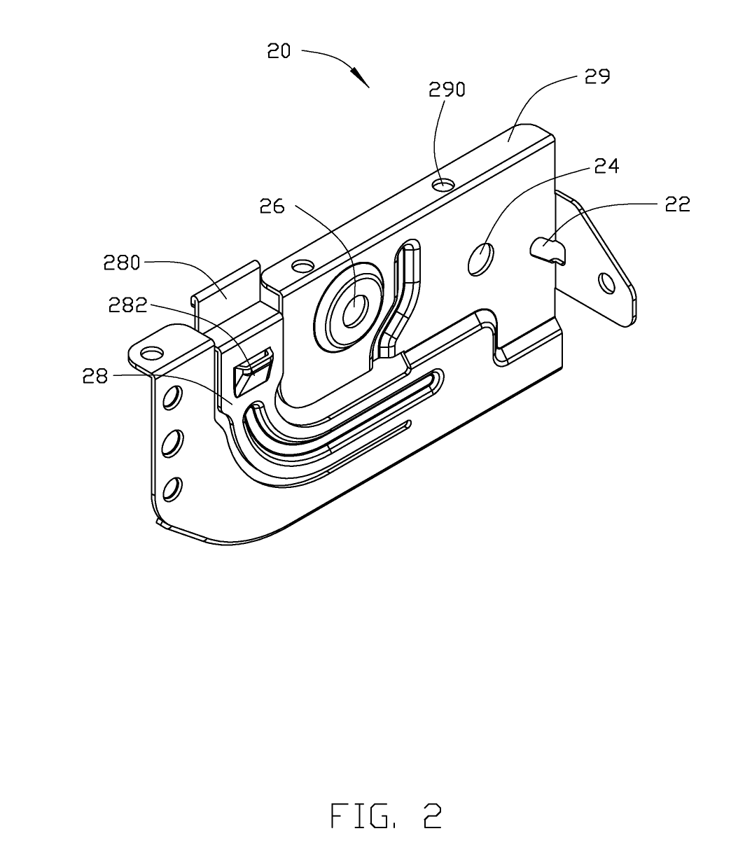

FIG. 2 illustrates the positioning member 20 of the electronic device enclosure 100. The positioning member 20 defines a first fixing hole 24, a second fixing hole 26, and a cutout 22 on an edge of the positioning member 20. The positioning member 20 includes a spring piece 28 and a second edge 29. The spring piece 28 includes an operation portion 280 and a stopper portion 282. A plurality of second locking holes 290 is defined in the second edge 29. In at least one embodiment, the stopper portion 282 can be a protrusion.

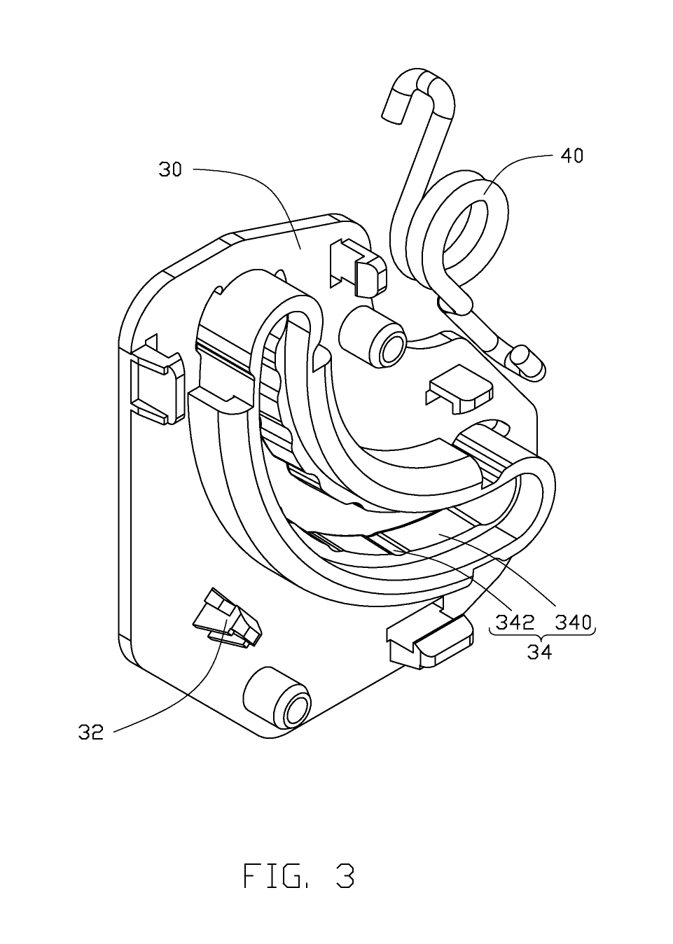

FIG. 3 illustrates one of the two mounting members 30 and one of the two supporting members 40 of the electronic device enclosure 100. The mounting member 30 includes a plurality of locking portions 32. A groove 34 is defined in the mounting member 30. The groove 34 includes a plurality of protrusions 340. The plurality of protrusions 340 is evenly spaced from each other. A notch 342 is formed by the two adjacent protrusions 340. In at least one embodiment, the groove 34 can be substantially arc shaped. In at least one embodiment, the supporting member 40 can be an elastic element, for example, a spring.

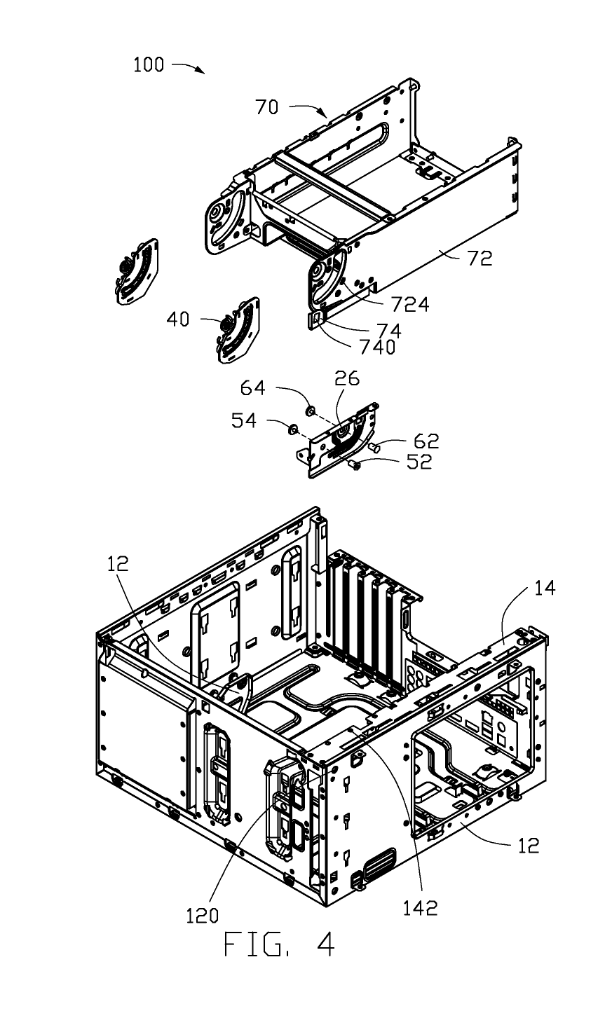

FIG. 4 illustrates the electronic device enclosure 100 from another angle. The shaft 50 includes a body 52 and a fixing portion 54. The rotary member 60 includes a pole 62 and a locking portion 64. The bracket 70 includes two side panels 72 and a positioning portion 74 extending from one of the two side panels 72. The two side panels 72 can be substantially parallel to each other. Each side panel 72 defines a shaft hole 720, a mounting space 722, a plurality of fastening holes 724, and a second gap 726. The plurality of fastening holes 724 is surrounding the mounting space 722. A positioning hole 740 is defined in the positioning portion 74.

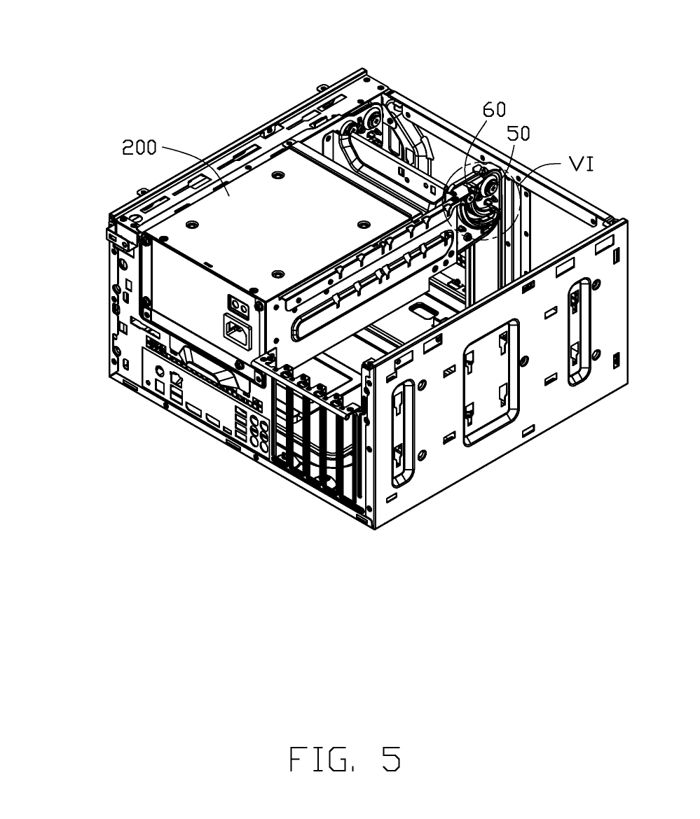

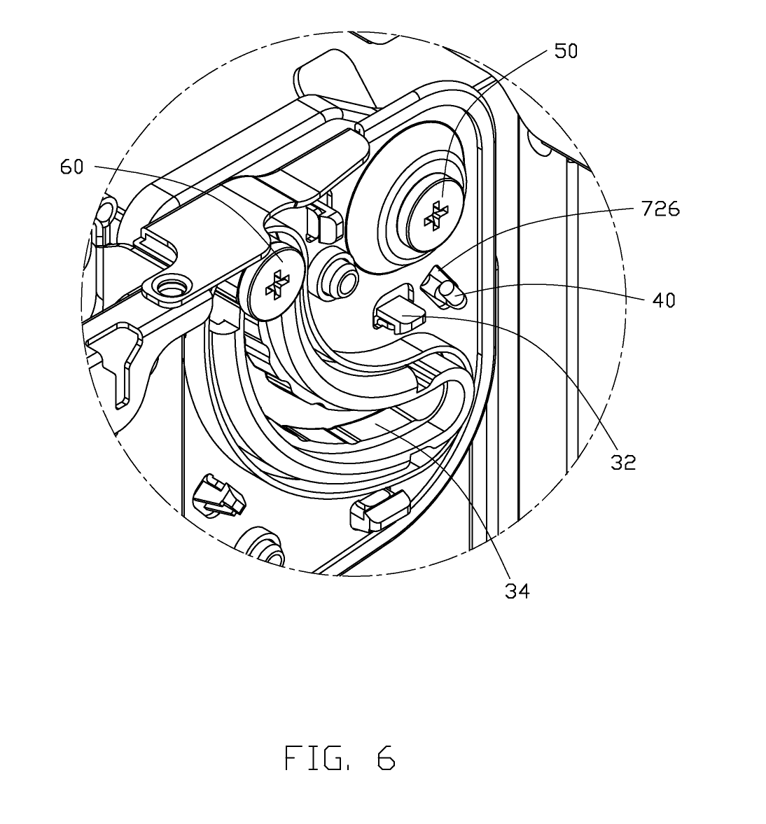

FIGS. 5-6 illustrate the electronic device enclosure 100 being assembled. The pole 62 of the rotary member 60 is received in the second fixing hole 26 of the positioning member 20 (see FIG. 4). The second edge 29 of the positioning member 20 is fixed to the first edge 14 of the chassis 10 by the plurality of second locking holes 290 and the plurality of first locking holes 142. The body 52 of the shaft 50 extends through the mounting hole 120 of the side plate 12, the first fixing hole 24 of the positioning member 20 and the supporting member 40. The plurality of locking portions 32 of the mounting member 30 is engaged in the plurality of fastening holes 724 of the bracket 70. Thus, the two mounting members 30 are fixed to the two side panels 72 of the bracket 70. The body 52 of the shaft 50 passes through the shaft hole 720 and is fixed to the fixing portion 54. The bracket 70 is rotatably connected to the chassis 10. The pole 62 of the rotary member 60 extends through the groove 34 and is fixed to the locking portion 64. The operation portion 280 is received in the receiving space 140 of the first edge 14. One of the two supporting members 40 is engaged in the first gap 124 and the second gap 726. Another supporting member 40 is engaged in the cutout 22 and the second gap 726.

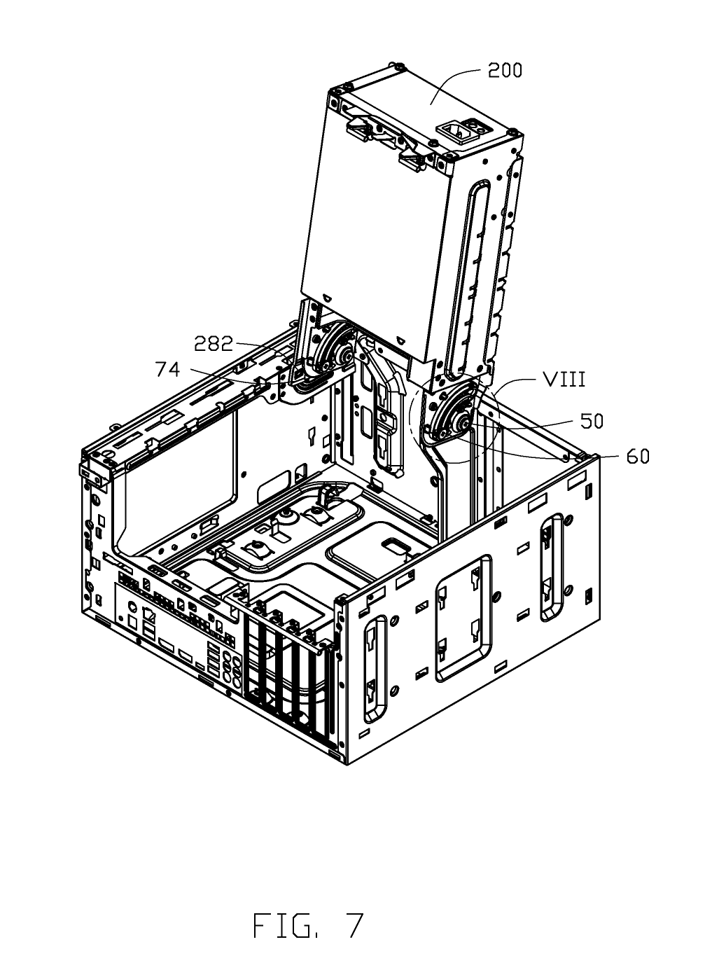

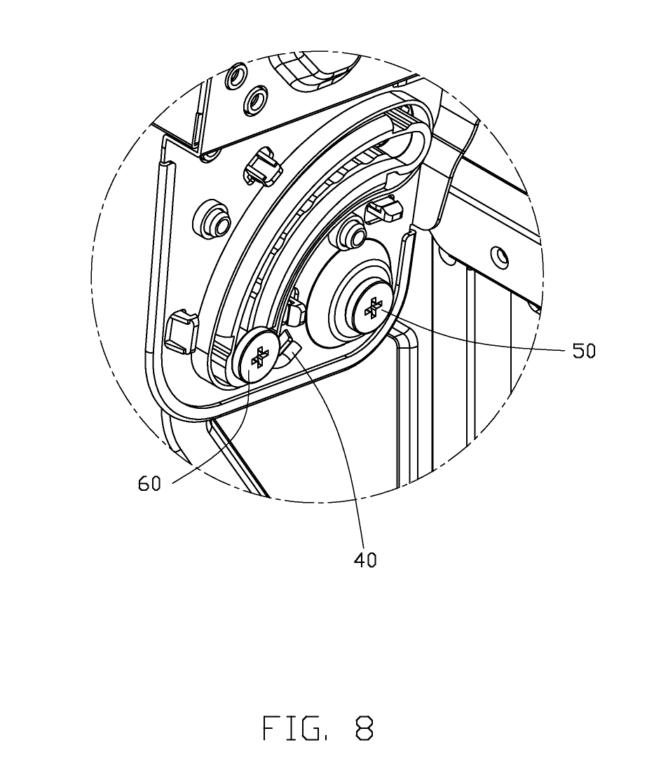

FIGS. 7-8 illustrate the bracket 70 rotating relative to the chassis 10. A power supply 200 is received in the bracket 70. The bracket 70 is rotated towards a first direction relative to the chassis 10. The groove 34 is slid relative to the rotary member 60 until the rotary member 60 is located in one of the plurality of notches 342 and is clamped between the two adjacent protrusions 340. The stopper portion 282 is received in the positioning hole 740 to prevent the bracket 70 from rotating towards a second direction relative to the chassis 10. The first direction is opposite to the second direction. The supporting member 40 can be elastically deformable to support the bracket 70 to prevent the bracket 70 from rotating towards the second direction relative to the chassis 10.

The embodiments shown and described above are only examples. Many details are often found in the art such as the other features of the electronic device enclosure. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electronic device enclosure comprising:
a chassis;
a bracket connected to the chassis;
a shaft configured to rotatably connect the chassis to the bracket; and
a supporting member sheathed with the shaft and having opposite ends of the supporting member are respectively fixed to the chassis and the bracket;
wherein when the bracket is rotated relative to the chassis in a first direction, and the supporting member is elastically deformed to support the bracket to prevent the bracket from rotating towards a second direction opposite to the first direction.

2. The electronic device enclosure of claim 1, wherein the supporting member is an elastic element, and the elastic element is a spring.

3. The electronic device enclosure of claim 2, wherein the chassis defines a first gap, the bracket defines a second gap, and opposite ends of the spring are engaged in the first gap and the second gap.

4. The electronic device enclosure of claim 1, further comprising a rotary member and a mounting member fixed to the bracket, wherein the mounting member defines a groove, and the rotary member is received in the groove.

5. The electronic device enclosure of claim 4, wherein the groove comprises a plurality of protrusions, a notch is formed by the two adjacent protrusions, the rotary member is received in the notch and is clamped between two adjacent protrusions.

6. The electronic device enclosure of claim 4, further comprising a positioning member fixed to the chassis, wherein the shaft is engaged with the positioning member to prevent the positioning member from moving.

7. The electronic device enclosure of claim 6, wherein the positioning member comprises a spring piece, the spring piece comprises a stopper portion, the bracket defines a positioning hole, and the stopper portion is received in the positioning hole to prevent the bracket from rotating relative to the chassis.

8. The electronic device enclosure of claim 7, wherein the spring piece comprises an operation portion, the chassis defines a receiving space, and the operation portion is configured to move within the receiving space to remove the stopper portion from the positioning hole.

9. The electronic device enclosure of claim 6, wherein the chassis defines a mounting hole, the positioning member defines a first fixing hole, the bracket defines a shaft hole, the shaft comprises a body and a fixing portion fixed to the body, and the body extends through the mounting hole, the first fixing hole, and the shaft hole.

10. The electronic device enclosure of claim 4, wherein the mounting member comprises a plurality of locking portions, the bracket defines a plurality of fastening holes, and the plurality of locking portions is engaged with the plurality of fastening holes to fix the mounting member to the bracket.

11. An electronic device enclosure comprising:
a chassis;
a bracket connected to the chassis;
a shaft configured to rotatably connect the chassis to the bracket;
a rotary member movably mounted to the bracket and substantially parallel to the shaft; and
a supporting member sheathed with the shaft and having opposite ends of the supporting member are respectively fixed to the chassis and the bracket;
wherein when the bracket is rotated relative to the chassis in a first direction, and the supporting member is elastically deformed to support the bracket to prevent the bracket from rotating towards a second direction opposite to the first direction.

12. The electronic device enclosure of claim 11, wherein the supporting member is an elastic element, and the elastic element is a spring.

13. The electronic device enclosure of claim 12, wherein the first gap and the second gap are near the shaft, and two opposite ends of the spring are engaged in the first gap and the second gap.

14. The electronic device enclosure of claim 11, further comprising a mounting member fixed to the bracket, wherein the mounting member defines a groove, and the rotary member is received in the groove.

15. The electronic device enclosure of claim 14, wherein the groove comprises a plurality of protrusions, a notch is formed by the two adjacent protrusions, the rotary member is received in the notch and is clamped between two adjacent protrusions.

16. The electronic device enclosure of claim 14, further comprising a positioning member fixed to the chassis, wherein the shaft is engaged with the positioning member to prevent the positioning member from moving.

17. The electronic device enclosure of claim 16, wherein the positioning member comprises a spring piece, the spring piece comprises a stopper portion, the bracket defines a positioning hole, and the stopper portion is received in the positioning hole to prevent the bracket from rotating relative to the chassis.

18. The electronic device enclosure of claim 17, wherein the spring piece comprises an operation portion, the chassis defines a receiving space, and the operation portion is configured to move within the receiving space to remove the stopper portion from the positioning hole.

19. The electronic device enclosure of claim 16, wherein the chassis defines a mounting hole, the positioning member defines a first fixing hole, the bracket defines a shaft hole, the shaft comprises a body and a fixing portion fixed to the body, and the body extends through the mounting hole, the first fixing hole, and the shaft hole.

20. The electronic device enclosure of claim 14, wherein the mounting member comprises a plurality of locking portions, the bracket defines a plurality of fastening holes, and the plurality of locking portions is engaged with the plurality of fastening holes to fix the mounting member to the bracket.
